(19) United States
(12) Patent Application Publication
(10) Pub. No.: US 2026/0247567 A1
(43) Pub. Date: Aug. 20, 2026

(54) FINNED COLD PLATE WITH MULTIPLE FLOW PATHS

(71) Applicant: AMD Design, LLC, Wilmington, DE (US)

(72) Inventors: Ting-Yu LIN, Fairfield, NJ (US); Atharva Manoj RAHANE, Jersey City, NJ (US)

(73) Assignee: AMD Design, LLC, Wilmington, DE (US)

(21) Appl. No.: 19/539,831

(22) Filed: Feb. 13, 2026

Related U.S. Application Data
(60) Provisional application No. 63/758,506, filed on Feb. 14, 2025.

(51) Int. Cl. H05K 7/20; F28F 3/04

(52) U.S. Cl. CPC H05K 7/20254; F28F 3/046; F28F 3/048

(57) ABSTRACT

The finned cold plate includes a plurality of fins forming a plurality of fin channels. The finned cold plate also includes at least one inlet port and at least one outlet port. The finned cold plate further includes an inlet duct system configured to receive fluid via the at least one inlet port and introduce the fluid into the fin channels at a plurality of inlet locations along the fin channels. The finned cold plate also includes an outlet duct system configured to gather fluid from a plurality of outlet locations along the fin channels and provide the fluid from the outlet locations to the at least one outlet port. In this way, overall heat-transfer may be improved while also minimizing heat-flux gradients.

### CROSS-REFERENCE TO RELATED APPLICATION

The subject application claims the benefit of U.S. Provisional Patent Application No. 63/758,506, filed on Feb. 14, 2025. The entire disclosure of U.S. Provisional Patent Application No. 63/758,506 is incorporated by this reference.

### FIELD

The present disclosure relates in general to liquid cooling of electronic components.

### BACKGROUND

Electronic components of servers (e.g., processing units) are using more and more power and producing more and more heat. To mitigate such heat, many servers utilize water cooling, where a cold plate is placed in thermal contact with one or more heat generating components. A fluid (e.g., PG20, PG25) is pumped through the cold plate, and the fluid absorbs the heat generated by the components such that it can be carried away from the servers.

Many electronic components do not have a uniform heat-flux and include one or more “hot spots” where heat flux is greater than other areas. Thus, even though an overall heat-transfer rate from the component to the fluid may be sufficient, such hot spots may continue to exist, which, without mitigation, can lead to component derating or failure. Furthermore, significant pressure drops across cold plates can stress pumps and other infrastructure components and can cause leaks and/or ruptures.

### SUMMARY

A cold plate for cooling an electronic component is described herein. The cold plate includes a plurality of fins forming a plurality of fin channels. The cold plate also includes at least one inlet port and at least one outlet port. The cold plate further includes an inlet duct system configured to receive fluid via the at least one inlet port and introduce the fluid into the fin channels at a plurality of inlet locations along the fin channels. The cold plate also includes an outlet duct system configured to gather fluid from a plurality of outlet locations along the fin channels and provide the fluid from the outlet locations to the at least one outlet port.

A system is also described herein. The system includes a heat-generating component and the cold plate above. A method is also described herein. The method includes transferring heat from the heat-generating component above to a base plate of the cold plate above. The method also includes causing a fluid to enter a fluid chamber of the cold plate via the influent port. The fluid chamber includes the fins forming the fin channels. The method further includes causing the fluid to flow into the fin channels at the inlet locations along the fin channels and to flow out of the fin channels at a plurality of outlet locations along the fin channels. The method also includes causing the fluid to exit the fluid chamber via the effluent port of the cold plate.

### BRIEF DESCRIPTION OF THE DRAWINGS

FIG. 1A illustrates a view of an example of a portion of a server with a cold plate, in accordance with this disclosure, installed therein.

FIG. 1B illustrates another view of the example of the portion of the server of FIG. 1A.

FIG. 2 illustrates an example of a base plate, in accordance with this disclosure.

FIG. 3 illustrates an example of first ducting plates, in accordance with this disclosure.

FIG. 4 illustrates an example of second ducting plates, in accordance with this disclosure.

FIG. 5 illustrates an example of third ducting plates, in accordance with this disclosure.

FIG. 6 illustrates an example of a fourth ducting plate, in accordance with this disclosure.

FIG. 7A illustrates a view of an example of perimeter plates, in accordance with this disclosure.

FIG. 7B illustrates another view of the example of the perimeter plates, in accordance with this disclosure.

FIG. 8 illustrates an example of a top plate, in accordance with this disclosure.

FIG. 9 illustrates an example of a method, in accordance with this disclosure.

FIG. 10 illustrates an example of a stepped first channel, in accordance with this disclosure.

FIG. 11 illustrates an example of another example of a first ducting plate, in accordance with this disclosure.

FIG. 12 illustrates an example of blocking plates, in accordance with this disclosure.

### DETAILED DESCRIPTION

### Overview

Conventional finned cold plates are often designed to have uniform one-dimensional uniform fluid velocity therethrough (e.g., single-phase). For example, fluid may enter channels between the fins via a first end of the fins, flow a length of the fins, and exit the channels via a second end of the fins. Even though the cold plates may allow for a sufficient overall heat-transfer rate from an associated component, the one-dimensional uniform flow may lead to hot spots on the component. Furthermore, such cold plates often cause significant pressure drops across the fins, which can stress pumps and other infrastructure components and can cause leaks and/or ruptures.

The cold plate described herein includes an inlet duct system configured to introduce fluid into fin channels at a plurality of inlet locations along the fin channels. The cold plate also includes an outlet duct system configured to gather fluid from a plurality of outlet locations along the fin channels.

By utilizing multiple inlet and outlet locations along the fins, effective flow lengths may be reduced. As such, a lower flow impedance and, thus, pressure drop across the cold plate may be realized. Furthermore, assuming a same pressure drop compared to conventional designs, flow rates may be increased, which may increase overall heat-transfer.

### Example Cold Plate—Component Interface

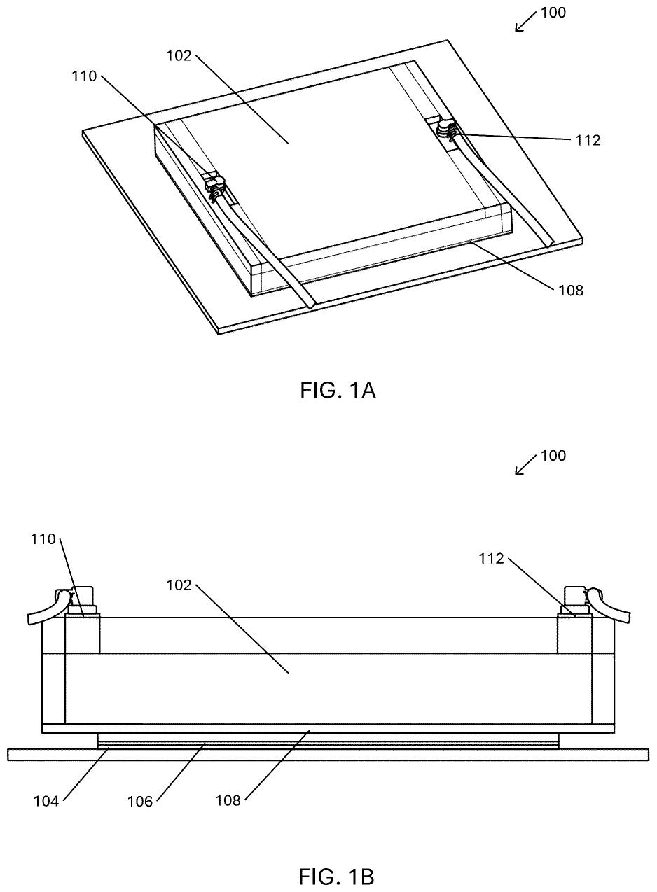

FIGS. 1A and 1B illustrate an example of a portion of a server 100 with a cold plate 102, in accordance with this disclosure, installed therein. FIG. 1A is a perspective view thereof, and FIG. 1B is an elevation view thereof. The cold plate 102 is mounted to an electronic component 104 (e.g., a processing unit). Between the cold plate 102 and the electronic component 104 is a thermal interface material (TIM) 106. The cold plate 102 includes a base plate 108 on a bottom of the cold plate 102 that interfaces with the TIM 106. The base plate 108 may include a pedestal or other structure that contacts the TIM 106.

The cold plate 102 comprises a body (e.g., structure) that forms a fluid cavity (not shown) configured to have a fluid (e.g., propylene glycol mixture) flow therethrough. The cold plate 102 forms at least one influent port 110 and at least one effluent port 112 that are in communication with the fluid cavity. Attached to the influent port 110 and the effluent port 112 are fittings, connectors, hoses, tubes, and/or pipes that are configured to supply the cold plate 102 with the fluid at a cooler temperature (e.g., via the influent port 110) and remove the fluid at a warmer temperature (e.g., after absorbing heat from the electronic component 104 via the effluent port 112).

Although the influent port 110 and the effluent port 112 are disposed on a top portion of the cold plate 102 in the illustrated example, one or both may be placed elsewhere relative to the cold plate 102 (e.g., on an end of the cold plate 102) without departing from the scope of this disclosure. Regardless of configuration, the cold plate 102 is configured such that fluid flows from the influent port 110 to the effluent port 112. In some implementations, a configuration of the fluid cavity within the cold plate 102 may be symmetric in a flow direction such that the influent port 110 and the effluent port 112 may be switched without affecting performance.

### Example Cold Plate

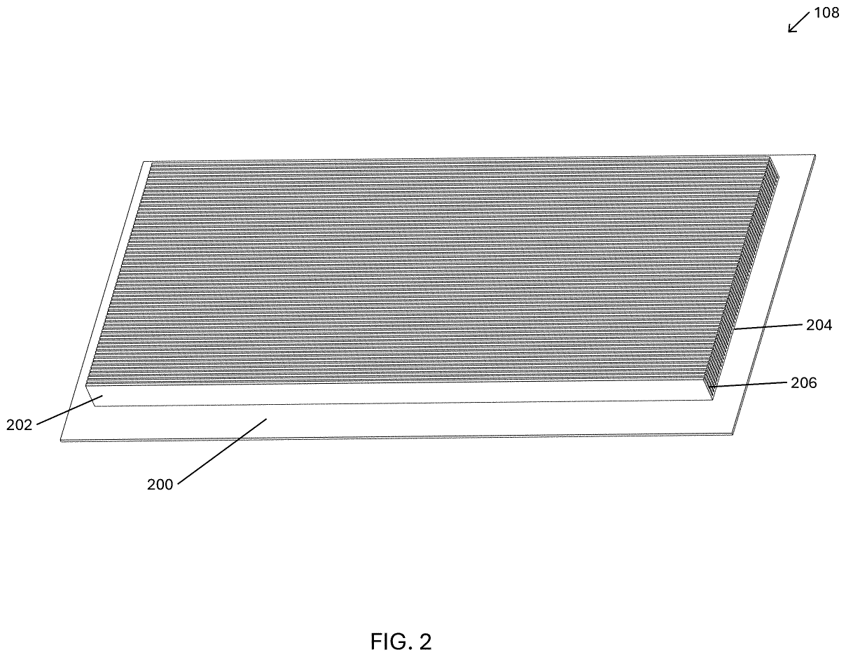

FIGS. 2-8 illustrate various components/portions of the cold plate 102, in accordance with this disclosure. The components may be separated to be formed of more components and/or combined with others of the components to be formed of less components. Furthermore, the order of the figures (e.g., how the cold plate 102 is built) may vary without departing from the scope of this disclosure. An assembly of plates (some forming a stack of layers) is described herein, although one or more of the structures may be non-plate structures. The cold plate 102 may be built via pre-formed components that are attached to one another, 3D printed, cast and/or machined, and so on out of one or more materials. For example, the base plate 108 may be formed of a copper alloy while other components may be formed of an aluminum alloy and/or a stainless steel.

FIG. 2. illustrates the base plate 108, in accordance with this disclosure. The base plate 108 includes a base portion 200 and a plurality of fins 202 attached thereto. The base portion 200 is configured to interface with the electronic component 104. The fins 202 are disposed on the base portion 200 such that space may be formed between the fins 202 and edges of the base portion 200. The fins 202 may be connected to one another via a fin-base portion 204, and the fins 202 form a plurality of channels 206. The channels 206 are formed between any two adjacent ones of the fins 202. The fins 202 (and, if implemented, the fin-base portion 204) may be integral with the base portion 200 or may be formed separately and attached thereto. For example, the fins 202 and fin-base portion 204 may be formed as a component and attached to the base portion 200 to form the base plate 108.

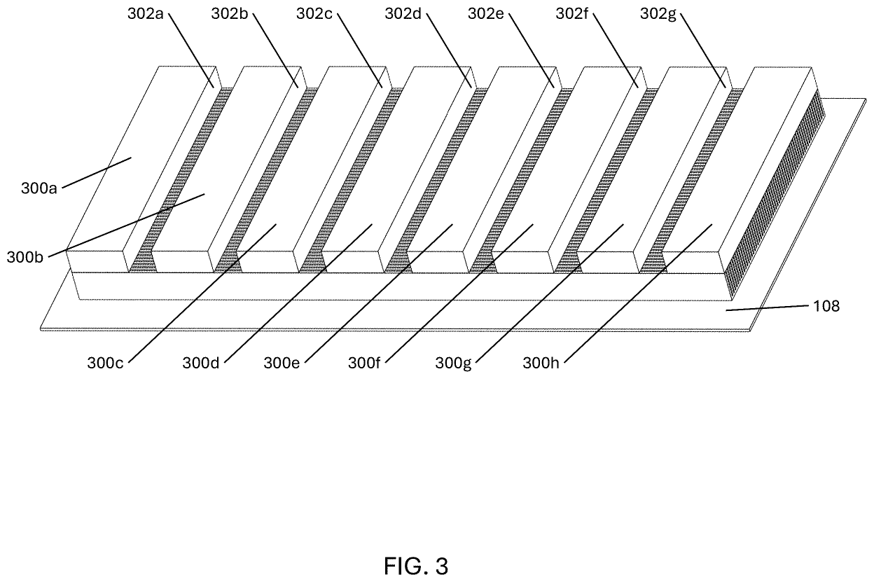

FIG. 3 illustrates a plurality of first ducting plates 300, in accordance with this disclosure. In the illustrated example there are eight first ducting plates 300 (e.g., first ducting plates 300a-h); however, any number of first ducting plates may be used. The first ducting plates 300 may span across the set of fins 202 such that they cover all the channels 206 in one dimension. Furthermore, end instances of the first ducting plates 300 (e.g., first ducting plates 300a and 300h) may be flush with ends of the fins 202.

The first ducting plates 300 form first channels 302 (e.g., first channels 302a-g) between any two adjacent first ducting plates 300. Although widths of the first channels 302 are consistent in the illustrated example, some of the first channels 302 may have different widths than others. It will become apparent from the description below, that the first channels 302 alternate between influent and effluent channels. Thus, first channels 302a, c, e, and g may be one of influent or effluent channels, and first channels 302b, d, and f may be another of influent or effluent channels.

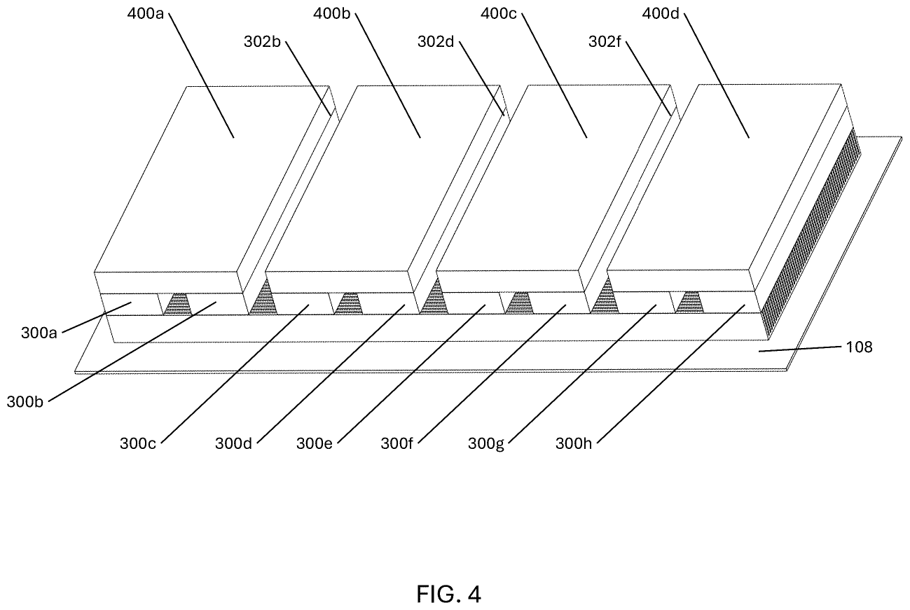

FIG. 4 illustrates a plurality of second ducting plates 400, in accordance with this disclosure. Each of the second ducting plates 400 covers two of the first ducting plates 300 starting with the ends (e.g., first ducting plates 300a and h) with the first channels 302 therebetween not being covered (e.g., 302b, d, and f). Thus, in the illustrated example, there are four second ducting plates 400 (e.g., second ducting plates 400a-d). Accordingly, the second ducting plates 400 close off every other first channel 302 in an up-down direction and extend every other first channel 302 in the up-down direction. In other words, first channels 302a, c, e, and g are capped by the second ducting plates 400 a-d, respectively, and first channels 302b, d, and f are extended up to a level of the second ducting plates 400. Although the second ducting plates 400 are flush with edges of the first ducting plates 300 in the left-right direction in the illustrated example, they may be inset therefrom. As long as the respective first channels 302 are capped, the second ducting plates 400 may vary in size.

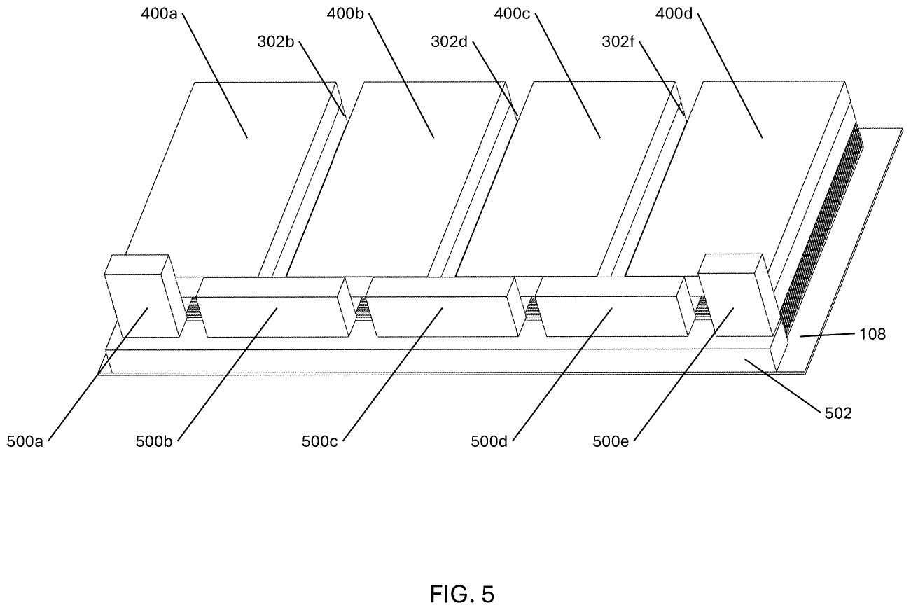

FIG. 5 illustrates an example of third ducting plates 500, in accordance with this disclosure. Third ducting plates 500 may be disposed at one end of the first channels 302. In the illustrated example, third ducting plates 500b-d cover ends of first channels 302b, d, and f. Third ducting plates 500b, c, and d may be flush with tops of the second ducting plates 400 and may be flush with sides of the first channels 302 or be outset therefrom (so as to not block flow there to/from). Third ducting plates 500a and e do not block the first channels 302 but may be disposed similarly to third ducting plates 500a and 500e (e.g., flush with ends of the first channels 300). The third ducting plates 500a and e may be taller than the third ducting plates 500 b-d. By doing so, a second channel may be formed therebetween (as discussed below). The third ducting plates 500 may be disposed on a third ducting plate base 502 that may rise to a level of the fins 202.

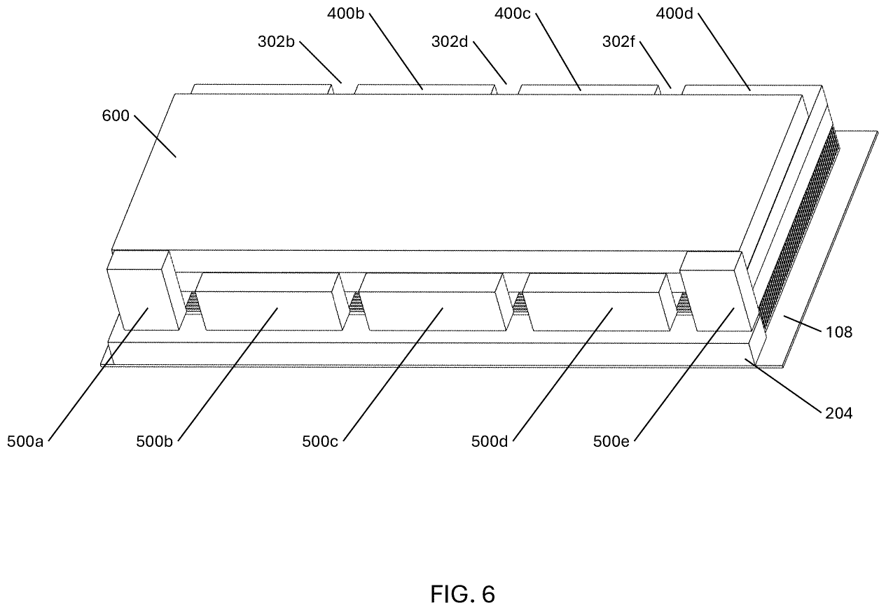

FIG. 6 illustrates an example of a fourth ducting plate 600, in accordance with this disclosure. Fourth ducting plate 600 abuts third ducting plates 500a and e and partially covers first channels 302b, d, and f. In other words, the fourth ducting plate 600, which may be flush with tops of third ducting plates 500a and e, may cover a majority of first channels 302b, d, and f.

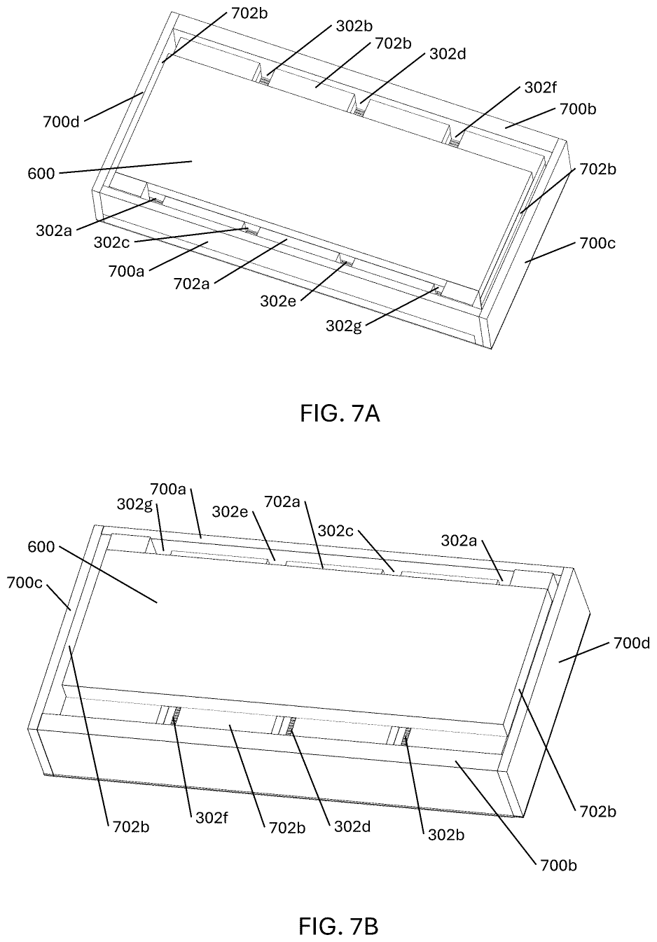

FIG. 7 illustrates an example of perimeter walls 700, in accordance with this disclosure. The perimeter walls 700 may extend from the base portion 200 and may be flush with a perimeter of the base portion 200. Although there are four separate portions that form the perimeter walls 700 in the illustrated example (e.g., perimeter walls 700a-d), two or more may be formed as a single structure. For example, the perimeter walls 700 may be formed as single rectangular structure.

The perimeter walls 700 form, in conjunction with the above features, second channels 702 (e.g., second channels 702a andb). Second channel 702a is formed by perimeter wall 700a, the fourth ducting plate 600, the third ducting plates 500, the second ducting plates 400, and the first ducting plates 300 to join first channels 302a, c, e, and g together.

Perimeter wall 700b caps off ends of the first channels 302 and forms, with the fourth ducting plate 600, the third ducting plates 500, the second ducting plates 400, and the first ducting plates 300, the second channel 702b. The second channel 702b connects first channels 302b, d, and f. Perimeter walls 700c andd form additional parts of the second channel 702b. As such, ends of the channels 206 are in communication with the second channel 702 (and therefor first channels 302b, d, and f). Accordingly, an amount of fluid influent locations along the channels 206 (e.g., locations where the fluid enters the channels 206) may be equal to a number of effluent locations along the channels 206 (e.g., locations where the fluid exits the channels 206. Conversely, the numbers of influent and effluent locations along the channels 206 may be different.

Adjacent influent and effluent locations have opposing fluid flow directions. In other words, fluid may combine from two influent locations (flowing in opposing directions) and exit via an effluent location (e.g., out a top of the channels 206). Fluid may enter the cold plate 102 and flow towards the channels 206 via the second channel 702a and flow away from the channels 206 via the second channel 702b and out of the cold plate 102. Conversely, fluid may enter the cold plate 102 and flow towards the channels 206 via the second channel 702b and flow away from the channels 206 via the second channel 702a and out of the cold plate 102. In other words, the flow direction may be in either direction.

At least one of the second channels 702 may have a flow direction, in at least a portion thereof, that is parallel to the channels 206.

Based on the above, it should be apparent that more or less first channels 302 may be implemented (via different numbers of plates). Furthermore, although the cold plate 102 is illustrated as symmetrical left to right, it may be asymmetrical. For example, one end of the channels 206 may be connected to the second channel 702a and another end of the channels 206 may be connected to the second channel 702b.

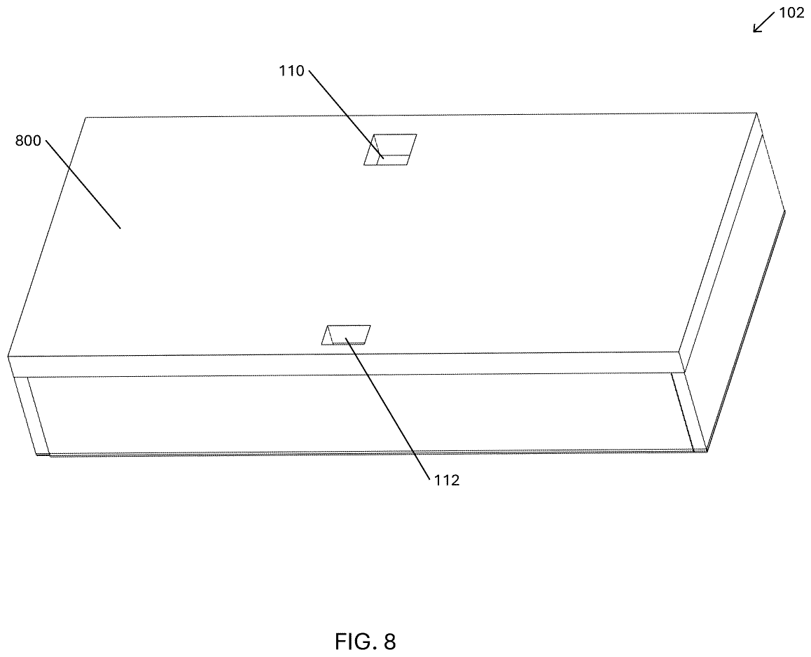

FIG. 8 illustrates a top plate 800, in accordance with this disclosure. The top plate 800 may be secured to the perimeter walls 700 to form the cold plate 102. In the illustrated example, the top plate 800 includes the influent port 110 and the effluent port 112. The influent port 110 is in communication with the second channel 702b, and the effluent port 112 is in communication with the second channel 702a. As discussed above, locations of the influent port 110 and the effluent port 112 may be switched (e.g., which second channel they communicate with) without departing from the scope of this disclosure. Furthermore, in some implementations, one or more of the influent port 110 or the effluent port 112 may be disposed in one of the perimeter walls 700 (while still in communication with respective second channels 702). Yet further, the size and/or shape of the influent port 110 and the effluent port 112 may vary, including having one be larger than the other (e.g., as illustrated).

### Method

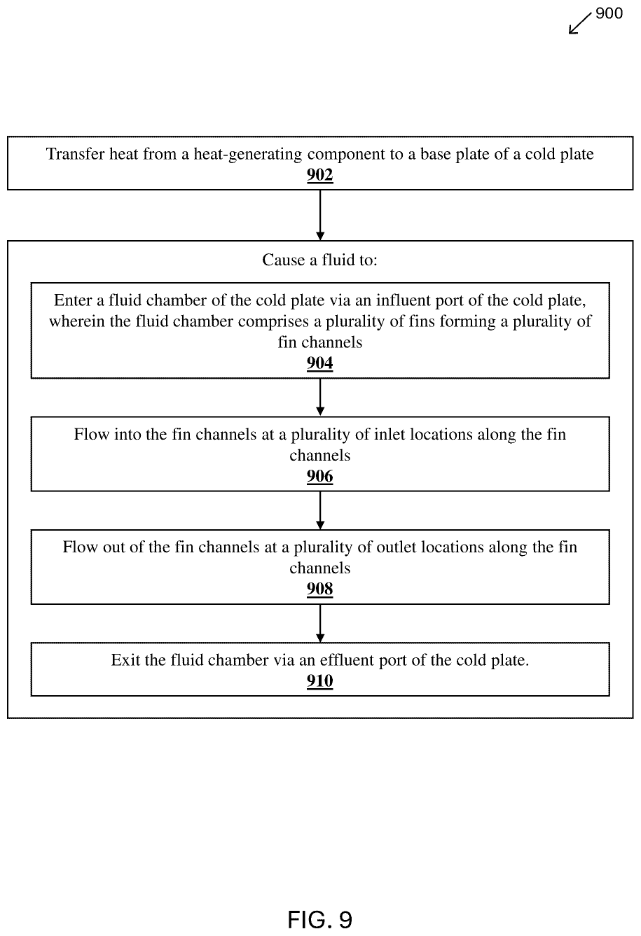

FIG. 9 illustrates an example of a method 900, in accordance with this disclosure. At step 902, heat from a heat-generating component is transferred to a base plate of a cold plate. For example, heat from the electronic component 104 may be transferred to the base plate 108 of the cold plate 102.

At step 904, fluid is caused to enter a fluid chamber of the cold plate via an influent port of the cold plate. The fluid chamber comprises a plurality of fins forming a plurality of fin channels. For example, fluid may be caused to enter the fluid chamber of the cold plate 102 via the influent port 110. The fluid chamber includes the fins 202 forming the channels 206.

At step 906, the fluid is caused to flow into the fin channels at a plurality of inlet locations along the fin channels. For example, the fluid may be caused to flow into the channels 206 via one of the second channels 702 and every other first channel 302.

At step 908, the fluid is caused to flow out of the fin channels at a plurality of outlet locations along the fin channels. For example, the fluid may be caused to flow out of the channels 206 via another of the second channels 702 and every other first channel 302 (interleaved with those from step 906).

At step 910, the fluid is caused to exit the fluid chamber via an effluent port of the cold plate. For example, the fluid may be caused to exit the fluid chamber of the cold plate 102 via the effluent port 112.

### Impedance/Flow Modifications

The above example cold plate 102 is configured to have generally even flow through the various portions of the fins 202. In other words, the above configuration may be useful when hot spots either don't exist, assuming overall heat transfer is sufficient. In some implementations, however, it may be beneficial to change flow impedance (and thus flow) through various channels 206 and/or portions of the channels 206. For example, flow may be decreased in cold spots and increased in hot spots. Any of the below flow modifications may be used in conjunction with one another without departing from the scope of this disclosure.

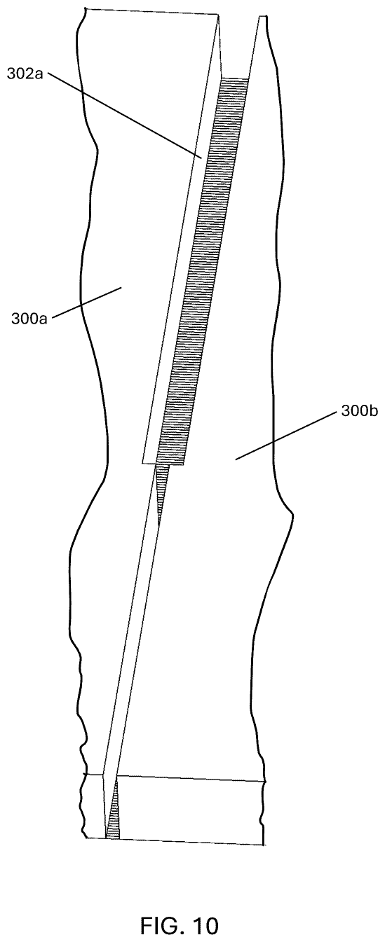

FIG. 10 illustrates an example of the first channel 302a with a stepped width, in accordance with this disclosure. Although the first channel 302a is shown, any of the first channels 302 may have the stepped width. Furthermore, if the first channel 302 is extended vertically (e.g., via another layer as discussed above with respect to FIG. 4), the stepped width may continue upward.

In the illustrated example, in a direction across the fins 202 (e.g., up/down), a width of the first channel 302a changes. Accordingly, flow may be restricted through the fins beneath the smaller width area (e.g., the lower part of the first channel 302a in FIG. 10). The flow may be influent or effluent into/out of the channels 206, respectively, depending on which first channel(s) 302 are implemented with the stepped width and/or how the cold plate 102 is configured.

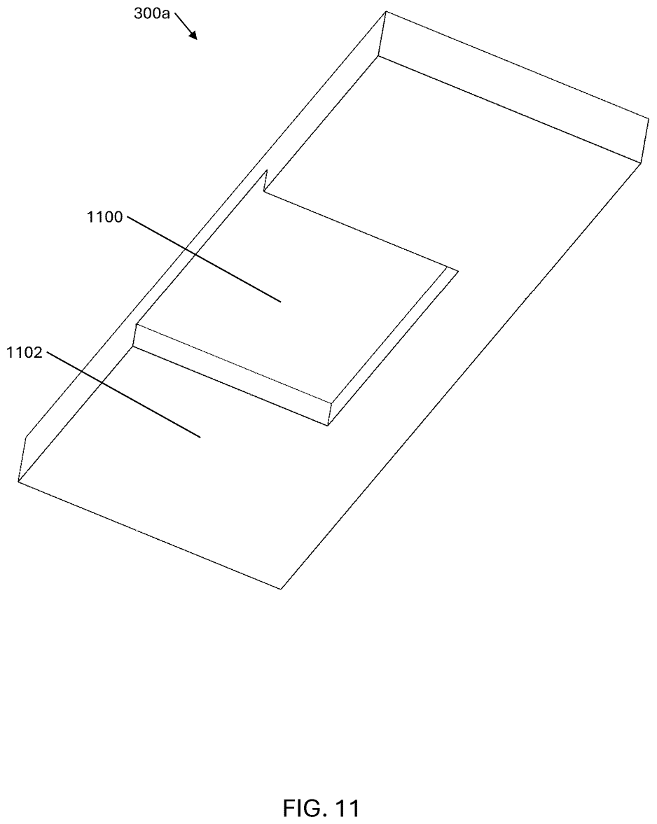

FIG. 11 illustrates an example of the first ducting plate 300a (e.g., in FIG. 3) with a cutout 1100 disposed therein. Although the first ducting plate 300a is shown, any of the first plates 300 may have cutouts disposed therein.

In the illustrated example, a surface 1102 is configured to be against the fins 202. In other words, the cutout 1100 is configured to be above the fins 202. Furthermore, the cutout 1100 is configured to run in a direction of the fins 202. As such, flow through an area of the fins 202 beneath the cutout 1100 may be increased relative to flow through an area of the fins 202 that is not beneath the cutout 1100.

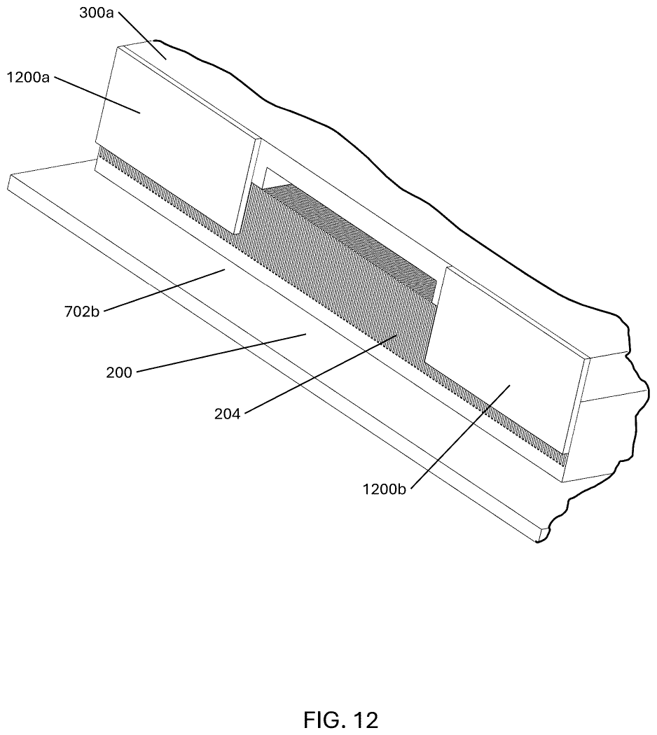

FIG. 12 illustrates an example of blocking plates 1200, in accordance with this disclosure. Although two blocking plates 1200 (e.g., blocking plate 1200a and blocking plate 1200b) are shown, any number of blocking plates may be used without departing from the scope of this disclosure.

The blocking plates 1200 are configured to be disposed on ends of the fins 202. For example, the blocking plates 1200 may be connected to one or more of the outermost first ducting plates 300 in FIGS. 3-6 (e.g., first ducting plate 300a and/or first ducting plate 300h in the above example) and/or disposed within the second channel 702b in FIGS. 7A and 7B. The blocking plates 1200 may be used to restrict flow into/out of ends of the channels 206 (e.g., into or out of the second channel 702b). By restricting flow there, more fluid may flow in areas not restricted by the blocking plates 1200 (e.g., the central channels 206 in the illustrated example). Thus, the illustrated example may be usable where a hot spot existed closer to a central section of the group of fins 202.

### Examples

Example 1: A cold plate for cooling an electronic component, the cold plate comprising: a plurality of fins forming a plurality of fin channels; at least one influent port; at least one effluent port; and a channel system configured to: receive fluid via the at least one influent port and introduce the fluid into the fin channels at a plurality of influent locations along the fin channels; and gather fluid from a plurality of effluent locations along the fin channels and provide the fluid from the effluent locations to the at least one effluent port.

Example 2: The cold plate of example 1, wherein the influent locations are interleaved with the effluent locations along the fin channels.

Example 3: The cold plate of example 1 or 2, the channel system is configured such that flows within the fin channels between adjacent influent locations are opposing.

Example 4: The cold plate of any previous example, wherein: at least one of the influent locations is above the fins; and at least one of the effluent locations is above the fins.

Example 5: The cold plate of example 4, wherein the at least one of the influent locations and the at least one of the effluent locations span the fin channels.

Example 6: The cold plate of any previous example, wherein: at least one of the influent locations is at an end of the fins; or at least one of the effluent locations is at an end of the fins.

Example 7: The cold plate of example 6, wherein: a plurality of the influent locations are at respective ends of the fins; or a plurality of the effluent locations are at respective ends of the fins.

Example 8: The cold plate of any previous example, wherein the channel system is formed via a plurality of plates.

Example 9: The cold plate of example 8, wherein a plurality of the plates are stacked in layers.

Example 10: The cold plate of any previous example, wherein the influent port and the effluent port are disposed in a top plate of the cold plate.

Example 11: The cold plate of any previous example, wherein the channel system comprises at least one channel with a portion parallel to the fin channels.

Example 12: The cold plate of any previous example, wherein a number of the influent locations is greater than or less than a number of the effluent locations.

Example 13: The cold plate of any previous example, wherein a number of the influent locations is equal to a number of the effluent locations.

Example 14: A system comprising: a heat-generating component; and a cold plate comprising: a plurality of fins forming a plurality of fin channels; at least one influent port; at least one effluent port; and a channel system configured to: receive fluid via the at least one influent port and introduce the fluid into the fin channels at a plurality of influent locations along the fin channels; and gather fluid from a plurality of effluent locations along the fin channels and provide the fluid from the effluent locations to the at least one effluent port.

Example 15: The system of example 14, wherein the influent locations are interleaved with the effluent locations along the fin channels.

Example 16: The system of example 14 or 15, wherein: at least one of the influent locations is above the fins; and at least one of the effluent locations is above the fins.

Example 17: The system of any of examples 14-16, wherein: at least one of the influent locations is at an end of the fins; or at least one of the effluent locations is at an end of the fins.

Example 18: The system of any of examples 14-17, wherein the channel system is formed via a plurality of plates.

Example 19: The system of example 18, wherein a plurality of the plates are stacked in layers.

Example 20: A method comprising: transferring heat from a heat-generating component to a base plate of a cold plate; and causing a fluid to: enter a fluid chamber of the cold plate via an influent port of the cold plate, wherein the fluid chamber comprises a plurality of fins forming a plurality of fin channels; flow into the fin channels at a plurality of inlet locations along the fin channels; flow out of the fin channels at a plurality of outlet locations along the fin channels; and exit the fluid chamber via an effluent port of the cold plate.

### Terminology

Server, as used herein, may refer to any computer or computing device that receives and/or provides information to clients on a computer network (e.g., wired, fiberoptic, wireless, or some combination thereof). The server may be an application server, a catalog server, a communications server, a computing server, a database server, a storage server, a machine learning server, a predictive analysis server, a fax server, a file server, a game server, a mail server, a media server, a print server, a sound server, a proxy server, a virtual server, a web server, some combination thereof, or a sever serving a different purpose or having a different type of architecture.

The server may include at least one processing unit configured to execute various operations of the server. The processing unit may include one or more processors, one or more central processing units (CPUs), one or more graphics processing units (GPUs), one or more application-specific integrated circuits (ASICs), one or more controllers or microcontrollers, one or more ladder logic controllers, one or more other types of control logic, conventional control systems (e.g., relays, switches, delays) or some combination thereof.

To cool the server, the server may include a cooling system. For example, the server may include a liquid cooling system configured to draw heat from the processing unit. The heat gathered from the processing unit can then be drawn away from the server (e.g., to an outside of a room or building). The cooling system may also, alternatively or additionally, include one or more fans configured to cool components of the server and/or work in conjunction with, or instead of, the liquid cooling system.

When implemented as a liquid cooling system, the cooling system may include one or more drip trays configured to capture leaking coolant from inside the server. The drip trays may be cascading (e.g., an effluent from one becomes an influent for another) and may contain one or more sensors configured to detect whether liquid is within the drip trays.

The liquid cooling system may also contain one or more fluid connections. The fluid connections may include quick-disconnect fittings attached to an external surface of the server. The quick disconnect fittings may be coupled to a heat exchanger within the server (e.g., proximate the processing unit). The fluid connections may be configured to attach to a cooling system or a manifold attached to other servers (e.g., within a same rack, within an adjacent rack, or in some other configuration).

The server may be a standard width (e.g., 19 inches or 21 inches) or a custom dimension. The server may also have any suitable depth. For example, the server may be arranged to not exceed approximately one meter in depth.

The server may contain computer-readable storage memory or media (CRM). The CRM may contain random access memory (RAM), electrically erasable programmable read-only memory (EEPROM), flash memory, one or more disk drives, or some combination thereof. The CRM may contain instructions that cause the processing unit to perform various functions of the server. The CRM may be software, firmware, or some combination thereof. The CRM may also include and/or hold data for the server to use for various functionalities.

In embodiments described herein, a server may optionally include a power supply configured to supply power to various components within the server. That is, in some cases, a server having power provided and/or distributed through a bus bar may not have internal power supply circuitry. Nevertheless, in cases where a server includes both internal power supply circuitry and ports arranged to receive power both a bus bar, the power supply may be configured to adapt or change incoming power (e.g., alternating current to direct current, stepping up or stepping down voltage, modulating power, shaping power signals, and the like). Furthermore, the internal power supply circuitry, when it is included, may be configured to supply different power to different components of the server.

The server may include one or more sensors configured to facilitate various functionalities of the server. For example, the sensors may include temperature, humidity, sound, tamper, vibration/shock, and/or moisture sensors. The sensors may also be disposed on an exterior of the server (e.g., on a rack or in a facility proximate the server).

The server may also include one or more clocks. The clocks may enable various functionality of the server to be timed and/or synchronized with another server or computing device.

The server may also include or otherwise be functional to implement one or more alarms. The alarms may be based on any of the sensors above and/or any other logic or instructions executing within the server. For example, the server may be able to notify a surrounding environment (e.g., via an audible tone) or another server or computing device (e.g., a server monitoring system) that a leak has occurred or that the server is overheating.

The server may be a stand-alone unit or may be attached to a server rack. The server rack (or simply rack), may hold any number of servers. Outside of the rack, the server may include a Level 10 assembly. When installed in the rack with one or more other servers, the server may become part of a Level 11 assembly (e.g., rack-level or multi-rack level).

The server may be installed and/or removed from the rack via any means. For example, guide rails may be used to slide the server into and out of the server rack while latches and/or fasteners may be used to secure the server to the server rack.

The rack may contain a centralized heat transfer system configured to draw heat from the servers disposed therein. The heat transfer system may include one or more manifolds directing/gathering liquid coolant to/from the servers. The heat transfer system may also include a side car unit or attach to a facility heat transfer system.

As part of the heat transfer system, the rack may contain one or more drip trays and/or associated systems. For example, the drip trays may contain a set of cascading drip trays and may have one or more alarms based on liquid being within one or more of the trays.

### Conclusion

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A cold plate for cooling an electronic component, the cold plate comprising:
a plurality of fins forming a plurality of fin channels;
at least one influent port;
at least one effluent port; and
a channel system configured to:
receive fluid via the at least one influent port and introduce the fluid into the fin channels at a plurality of influent locations along the fin channels; and
gather fluid from a plurality of effluent locations along the fin channels and provide the fluid from the effluent locations to the at least one effluent port.

2. The cold plate of claim 1, wherein the influent locations are interleaved with the effluent locations along the fin channels.

3. The cold plate of claim 2, the channel system is configured such that flows within the fin channels between adjacent influent locations are opposing.

4. The cold plate of claim 1, wherein:
at least one of the influent locations is above the fins; and
at least one of the effluent locations is above the fins.

5. The cold plate of claim 4, wherein the at least one of the influent locations and the at least one of the effluent locations span the fin channels.

6. The cold plate of claim 1, wherein:
at least one of the influent locations is at an end of the fins; or
at least one of the effluent locations is at an end of the fins.

7. The cold plate of claim 6, wherein:
a plurality of the influent locations are at respective ends of the fins; or
a plurality of the effluent locations are at respective ends of the fins.

8. The cold plate of claim 1, wherein the channel system is formed via a plurality of plates.

9. The cold plate of claim 8, wherein a plurality of the plates are stacked in layers.

10. The cold plate of claim 1, wherein the influent port and the effluent port are disposed in a top plate of the cold plate.

11. The cold plate of claim 1, wherein the channel system comprises at least one channel with a portion parallel to the fin channels.

12. The cold plate of claim 1, wherein a number of the influent locations is greater than or less than a number of the effluent locations.

13. The cold plate of claim 1, wherein a number of the influent locations is equal to a number of the effluent locations.

14. A system comprising:
a heat-generating component; and
a cold plate comprising:
a plurality of fins forming a plurality of fin channels;
at least one influent port;
at least one effluent port; and
a channel system configured to:
receive fluid via the at least one influent port and introduce the fluid into the fin channels at a plurality of influent locations along the fin channels; and
gather fluid from a plurality of effluent locations along the fin channels and provide the fluid from the effluent locations to the at least one effluent port.

15. The system of claim 14, wherein the influent locations are interleaved with the effluent locations along the fin channels.

16. The system of claim 14, wherein:
at least one of the influent locations is above the fins; and
at least one of the effluent locations is above the fins.

17. The system of claim 14, wherein:
at least one of the influent locations is at an end of the fins; or
at least one of the effluent locations is at an end of the fins.

18. The system of claim 14, wherein the channel system is formed via a plurality of plates.

19. The system of claim 18, wherein a plurality of the plates are stacked in layers.

20. A method comprising:
transferring heat from a heat-generating component to a base plate of a cold plate; and
causing a fluid to:
enter a fluid chamber of the cold plate via an influent port of the cold plate, wherein the fluid chamber comprises a plurality of fins forming a plurality of fin channels;
flow into the fin channels at a plurality of inlet locations along the fin channels;
flow out of the fin channels at a plurality of outlet locations along the fin channels; and
exit the fluid chamber via an effluent port of the cold plate.
